(19) United States
(12) Patent Application Publication
(10) Pub. No.: US 2019/0296033 A1
(43) Pub. Date: Sep. 26, 2019

(54) SEMICONDUCTOR MEMORY DEVICE

(71) Applicant: Toshiba Memory Corporation, Minato-ku (JP)

(72) Inventor: Shigeru KINOSHITA, Yokohama (JP)

(73) Assignee: Toshiba Memory Corporation, Minato-ku (JP)

(21) Appl. No.: 16/030,079

(22) Filed: Jul. 9, 2018

(30) Foreign Application Priority Data
Mar. 22, 2018 (JP) 2018-054380

(51) Int. Cl. H01L 27/11556; H01L 27/11582; H01L 29/10; H01L 29/06

(52) U.S. Cl. CPC H01L 27/11556; H01L 29/0649; H01L 29/1037; H01L 27/11582

(57) ABSTRACT

According to one embodiment, a semiconductor memory device includes a substrate, a stacked body, columnar parts, and insulating members. The stacked body is provided above the substrate, and includes electrode films stacked to be separated one another. The columnar parts are provided in the stacked body, and each of the columnar parts includes a semiconductor part. The insulating members are provided in the stacked body, and each of the insulating members includes insulating portions disposed alternately with the columnar parts. The insulating members include first, second, and third insulating members. The first and second insulating members are disposed to be separated each other. The third insulating member is positioned to be separated from the first and second insulating members. The insulating portions include a first insulating portion and second insulating portions. The columnar parts include first, second, third and fourth columnar parts.

### CROSS-REFERENCE TO RELATED APPLICATIONS

This application is based upon and claims the benefit of priority from Japanese Patent Application No. 2018-054380, filed on Mar. 22, 2018; the entire contents of which are incorporated herein by reference.

### FIELD

Embodiments described herein relate generally to a semiconductor memory device.

### BACKGROUND

A semiconductor memory device having a 3-dimensional structure has been proposed. In the semiconductor memory device, a memory density is desired to be improved.

### BRIEF DESCRIPTION OF THE DRAWINGS

FIG. 1 is a plan view showing a semiconductor memory device according to a first embodiment;

FIG. 2 is a plan view illustrating a portion of the semiconductor memory device according to the first embodiment;

FIG. 3 is a cross-sectional view illustrating the semiconductor memory device according to the first embodiment;

FIG. 4 is a cross-sectional view illustrating the semiconductor memory device according to the first embodiment;

FIG. 5A and FIG. 5B are schematic views showing a method for manufacturing the semiconductor memory device according to the first embodiment;

FIG. 6A and FIG. 6B are schematic views showing a method for manufacturing the semiconductor memory device according to the first embodiment;

FIG. 7A and FIG. 7B are schematic views showing a method for manufacturing the semiconductor memory device according to the first embodiment;

FIG. 8A and FIG. 8B are schematic views showing a method for manufacturing the semiconductor memory device according to the first embodiment;

FIG. 9A and FIG. 9B are schematic views showing a method for manufacturing the semiconductor memory device according to the first embodiment;

FIG. 10 is a schematic cross-sectional view showing an another semiconductor memory device according to the first embodiment;

FIG. 11 is a schematic plan view illustrating a semiconductor memory device according to a second embodiment;

FIG. 12 is a schematic cross-sectional view illustrating the semiconductor memory device according to the second embodiment;

FIG. 13 is a schematic cross-sectional view illustrating a portion of an another semiconductor memory device according to the second embodiment;

FIG. 14 is a schematic plan view illustrating a method for manufacturing the semiconductor memory device according to the second embodiment;

FIG. 15 is a schematic plan view illustrating a method for manufacturing the semiconductor memory device according to the second embodiment;

FIG. 16 is a schematic plan view illustrating a method for manufacturing the semiconductor memory device according to the second embodiment;

FIG. 17 is a schematic plan view illustrating a method for manufacturing the semiconductor memory device according to the second embodiment; and

FIG, 18 is a schematic plan view illustrating a still another semiconductor memory device according to the second embodiment.

### DETAILED DESCRIPTION

According to one embodiment, a semiconductor memory device includes a substrate, a stacked body, a plurality of columnar parts, and a plurality of insulating members. The stacked body is provided above the substrate, and includes a plurality of electrode films stacked to be separated one another in a first direction. The columnar parts are provided in the stacked body, and each of the columnar parts includes a semiconductor part extending in the first direction. The insulating members are provided in the stacked body, and each of the insulating members includes a plurality of insulating portions disposed alternately with the columnar parts along a second direction crossing the first direction and parallel to an upper surface of the substrate. The insulating members include a first insulating member, a second insulating member and a third insulating member. The first insulating member and the second insulating member are disposed to be separated each other along the second direction. The third insulating member is positioned to be separated from the first insulating member and the second insulating member along a third direction crossing the second direction and parallel to the upper surface of the substrate. Each of the first insulating member and the second insulating member overlaps a respective portion of the third insulating member when viewed from the third direction. The insulating portions include at least one first insulating portion and a plurality of second insulating portions. The first insulating portion is positioned between the second insulating portions. The electrode films include a first portion and a second portion. The first portion is positioned in the second direction between the first insulating member and the second insulating member. The second portion is connected to the first portion and is positioned in the third direction between the first insulating member and the third insulating member and between the second insulating member and the third insulating member. The second portion extends in the second direction.

The columnar parts include a first columnar part, a second columnar part, a third columnar part and a fourth columnar part. The first columnar part is positioned between the first insulating portion of the first insulating member and the second insulating portion of the first insulating member. The second columnar part is positioned between the first insulating portion of the second insulating member and the second insulating portion of the second insulating member. The second insulating portion of the first insulating member and the second insulating portion of the second insulating member oppose via the first portion of the electrode films. The third columnar part and the fourth columnar part oppose via the first insulating portion of the third insulating member. A distance in the second direction of the third columnar part and the fourth columnar part is shorter than a distance in the second direction of the first columnar part and the second columnar part.

Various embodiments will be described hereinafter with reference to the accompanying drawings.

The drawings are schematic and conceptual; and the relationships between the thickness and width of portions, the proportions of sizes among portions, etc., are not necessarily the same as the actual values thereof. Further, the dimensions and proportions may be illustrated differently among drawings, even for identical portions.

In the specification and drawings, components similar to those described or illustrated in a drawing thereinabove are marked with like reference numerals, and a detailed description is omitted as appropriate.

### First Embodiment

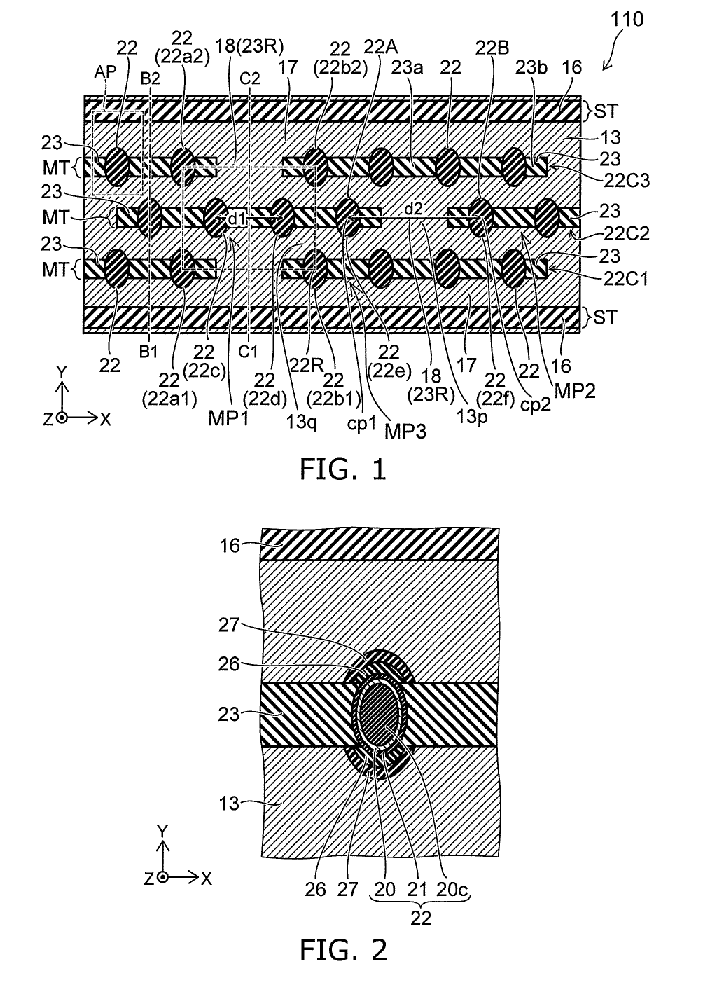

FIG. 1 is a plan view illustrating a semiconductor memory device according to a first embodiment.

FIG. 2 is a plan view illustrating a portion of the semiconductor memory device according to the first embodiment.

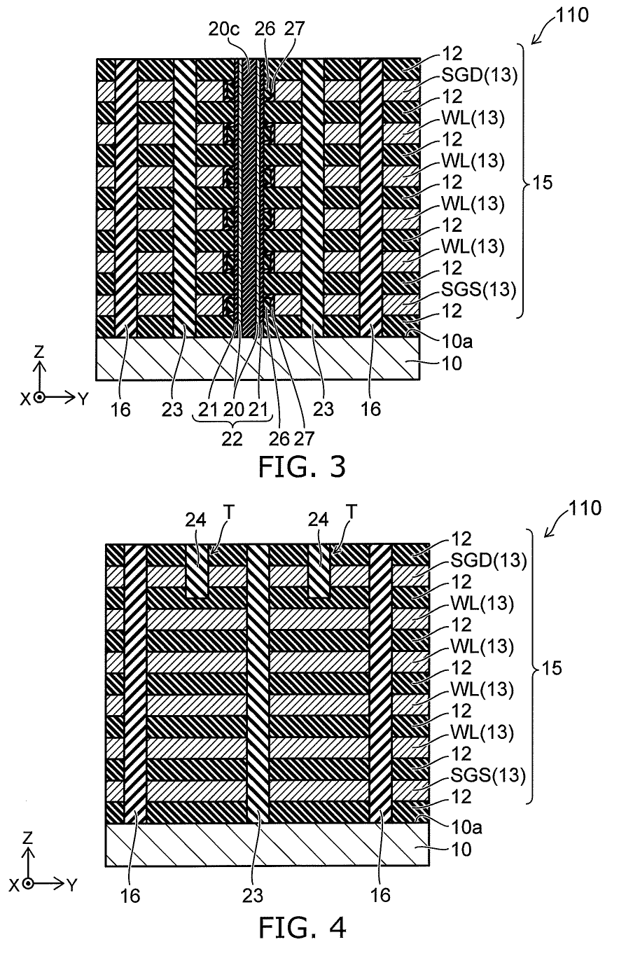

FIG. 3 and FIG. 4 are cross-sectional views illustrating the semiconductor memory device according to the first embodiment.

FIG. 2 shows a portion AP of FIG. 1. FIG. 3 is a B1-B2 line cross-sectional view of FIG. 1. FIG. 4 is a C1-C2 line cross-sectional view of FIG. 1.

As shown in FIG. 1 to FIG. 4, a semiconductor memory device 110 according to the embodiment is provided with a substrate 10. The substrate 10 includes, for example a single crystal of silicon (Si).

In the specification, for convenience of description, an XYZ orthogonal coordinate system is adopted. Directions parallel to an upper surface 10a of the substrate 10 and orthogonal to each other are taken as “X-direction” and “Y-direction”, and a direction perpendicular to the upper surface 10a is taken as “Z-direction”. In one example, the Z-direction is a first direction.

As shown in FIG. 1, FIG. 3 and FIG. 4, the semiconductor memory device 110 is provided with a stacked body 15, an insulating member 16, a columnar part 22, and an insulating member 23.

As shown in FIG. 3 and FIG. 4, the stacked body 15 is provided with multiple insulating films 12 and multiple electrode films 13, and the insulating films 12 and the electrode films 13 are stacked alternately one layer by one layer in the Z-direction. A stacked number of the insulating films 12 and the electrode films 13 is arbitrary. The insulating films 12 include, for example, a silicon oxide (SiO). The electrode films 13 include, for example, polysilicon. The electrode films 13 may include, for example, a metal material such as tungsten (W) or the like.

For example, the electrode film 13 positioned at the lowest layer of the multiple electrode films 13 is a source side selection gate SGS, and is provided on the substrate 10 via the insulating films 12. For example, the electrode film 13 positioned at the uppermost layer of the multiple electrode films 13 is a drain side selection gate SGD. For example, the electrode films 13 provided between the electrode film 13 at the lowest layer (source side selection gate SGS) and the electrode film 13 at the uppermost layer (drain side selection gate SGD) of the multiple electrode films 13 are word lines WL. FIG. 1 corresponds to a view of the electrode films 13 of the stacked body 15 (for example, source side selection gate SGS and word lines WL) viewed from the upper surface.

For example, the stacked body 15 is provided multiply on the substrate 10, and the multiple stacked bodies are disposed to be separated one another along the Y-direction.

The insulating member 16 is provided between the stacked bodies 15. The insulating member 16 pierces the stacked bodies 15 in the Z-direction. The insulating member 16 is positioned in a slit ST formed in the stacked body 15. The shape of the insulating member 16 is longitudinal in the X-direction and is a plate shape spreading in the XZ-plane. The insulating member 16 includes, for example, a silicon oxide. The stacked bodies 15 and elements (for example, columnar part 22) in the stacked bodies 15 are separated by the insulating member 16.

The columnar part 22 is provided multiply in the stacked bodies 15. As shown in FIG. 2 and FIG. 3, the columnar part 22 includes a silicon pillar 20 (semiconductor part) and an insulating film 21. The insulating film 21 is, for example, a tunnel insulating film.

The silicon pillar 20 extends in the stacked bodies 15 in the Z-direction. The silicon pillar 20 includes, for example, polysilicon, and has a cylindrical shape or an elliptic cylindrical shape. A lower end of the silicon pillar 20 contacts the substrate 10. The silicon pillar 20 functions as a channel. In this example, a core part 20c including a silicon oxide is provided in the silicon pillar 20, for example.

The insulating film 21 is provided on a side surface of the silicon pillar 20. If a voltage within a range of a drive voltage of the semiconductor memory device 110 is applied to the insulating film 21, a current flows through the insulating film 21. The insulating film 21 includes, for example, a silicon oxide. The insulating film 21 may be, for example, an ONO film stacked with a silicon oxide layer, a silicon nitride layer and a silicon oxide layer in this order.

The insulating member 23 pierces the stacked bodies 15 in the Z-direction. The insulating member 23 is positioned in a memory trench MT formed in the stacked body 15. The insulating member 23 includes, for example, a silicon oxide.

Disposition of the columnar part 22 and the insulating member 23 is described later.

As shown in FIG. 4, an insulating member 24 extending in the X-direction is provided in an upper portion of the stacked body 15. The insulating member 24 is positioned in a groove T formed in an upper portion of the stacked body 15. The insulating member 24 divides one from the top or multiple electrode films 13. The one from the top or multiple electrode films 13 of electrode films 13 is divided by the columnar part 22, the insulating member 23 and the insulating member 24. Thereby, multiple line-shaped drain side selection gates SGD extending in the X-direction are formed. In the embodiment, one electrode film 13 between the insulating members 16 is divided by the columnar part 22, the insulating member 23 and the insulating member 24, and four drain side selection gates SGD extending in the X-direction and disposed in the Y-direction are formed.

The shape of the electrode films 13 provided below the insulating member 24 is defined by the columnar part 22 and the insulating member 23. In the embodiment, a source side selection gate SGS and word lines WL are configured by these electrode films 13, and the electrode films 13 include four interconnection portions 17 disposed along the X-direction and the Y-direction, and connecting portions 18 extending in the X-direction and connecting the interconnection portions 17.

As shown in FIG. 2 and FIG. 3, charge storage films 26 are provided between the insulating film 21 and the electrode films 13. The charge storage films 26 are films capable of storing a charge, and include a material having electron trap sites. For example, the charge storage films 26 include a silicon nitride (SiN). The charge storage films 26 are positioned on both sides in the Y-direction of the columnar part 22 and not positioned on both sides in the X-direction. Thereby, the charge storage films 26 disposed on the both sides in the Y-direction of one columnar part 22 are separated each other. For example, the shape of the charge storage films 26 is a semicircular shape which makes a half circle on the side surface of the columnar part 22. The charge storage films 26 may be, for example, a floating gate surrounded by an insulator.

An insulating film 27 is provided between the charge storage film 26 and the electrode film 13. The insulating film 27 is, for example, a block insulating film. The insulating film 27 is a film in which a current does not substantially flow even if the voltage within the drive voltage of the semiconductor memory device 110 is applied to. The insulating film 27 includes, for example, a silicon oxide. The insulating film 27 may be a stacked film stacked with a silicon oxide layer and an aluminum oxide layer from a side of the charge storage film 26.

An upper interconnection (not shown) is provided on the stacked body 15. The upper interconnection includes bit lines extending in the Y-direction and connected to the silicon pillar 20 via a plug (not shown).

A drain side selection transistor is configured for each cross portion of the drain side selection gates SGD and the silicon pillar 20. A source side selection transistor is configured for each cross portion of the source side selection gates SGS and the silicon pillar 20. A memory cell is configured for each cross portion of the word lines and the silicon pillar 20. Thereby, multiple memory cells are connected in series along the silicon pillar 20, the source side selection transistor and the drain side selection transistor are connected to the both ends, and a NAND string is configured.

Hereinafter, an example of disposition of the columnar part 22 and the insulating member 23 will be described.

As shown in FIG. 1, the multiple columnar parts 22 and the multiple insulating portions are disposed alternately in a second direction (for example, X-direction). The multiple columnar parts 22 are disposed along multiple columns extending in the X-direction. For example, positions of the columnar parts 22 in the X-direction are different between adjacent columns in the Y-direction. In other words, the columnar parts 22 are arranged in a staggered arrangement when viewed from the Z-direction. In the example of FIG. 1, the multiple columnar parts 22 are disposed along a first column 22C1, a second column 22C2 and a third column 22C3, and positions of the columnar parts 22 in the X-direction are different between the first column 22C1 and the second column 22C2, and different between the second column 22C2 and the third column 22C3. The positions of the columnar parts 22 in the X-direction are generally the same between the first column 22C1 and the third column 22C3. The number of columns extending in the X-direction is arbitrary.

The multiple columnar parts 22 disposed in the second column 22C2 are positioned in a region 22R surrounded by the columnar parts 22a1, 22b1 disposed in the first column 22C1 and the columnar parts 22a2, 22b2 disposed in the third column 22C3. For example, columnar parts 22c, 22d disposed in the second column 22C2 are positioned in the region 22R. The region 22R is a region formed by centers of the columnar parts 22a1, 22b1, 22a2, 22b2, and is a rectangular region as viewed from the Z-direction. The center of the columnar parts 22 corresponds to the center of the cylinder in the case of the columnar parts 22 having a cylindrical shape.

The multiple insulating members 23 are disposed along the first column 22C1, the second column 22C2 and the third column 22C3 extending in the X-direction. The multiple insulating members 23 are disposed to be separated one another in each of the first column 22C1, the second column 22C2 and the third column 22C3. The number of the insulating members 23 disposed along the respective columns is arbitrary.

A region 23R is formed between the adjacent insulating members 23 in the X-direction, and the adjacent insulating members 23 in the X-direction are divided by the region 23R. A portion of the stacked body 15 (for example, connection portion 18) is positioned in the region 23R. As shown in FIG. 4, the insulating member 24 is positioned in the region 23R.

For example, when viewed from the Y-direction, a portion of the insulating member 23 disposed along the first column 22C1 overlaps a portion of the insulating member 23 disposed along the second column 22C2. For example, when viewed from the Y-direction, the portion of the insulating member 23 disposed along the second column 22C2 overlaps a portion of the insulating member 23 disposed along the third column 22C3.

For example, when viewed from the Y-direction, the insulating member 23 disposed along the first column 22C1 overlaps the insulating member 23 disposed along the third column 22C3.

The insulating member 23 includes an insulating portion 23a and an insulating portion 23b. The insulating portion 23a opposes the columnar part 22 in the X-direction. For example, the insulating portion 23a contacts the insulating film 21 of the columnar part 22 in the X-direction.

The insulating portion 23b opposes the columnar part 22 at one end in the X-direction, and opposes the portion (for example, connection portion 18) of the stacked body 15 at other end in the X-direction. For example, the insulating portion 23b contacts the insulating film 21 of the columnar part 22 at the one end in the X-direction, and contacts the portion (for example, connection portion 18) of the stacked body 15 at the other end in the X-direction.

In the example of FIG. 1, the insulating member 23 is formed of three insulating portions 23a and two insulating portions 23b. The columnar part 22 and the insulating portion (insulating portion 23a or insulating portion 23b) of the insulating member 23 are alternately disposed in the X-direction. The insulating portion 23b, the columnar part 22, the insulating portion 23a, the columnar part 22, the insulating portion 23a, the columnar part 22, the insulating portion 23a, the columnar part 22, the insulating portion 23b are disposed in the X-direction. The number of each of the insulating portions 23a, 23b and the columnar parts 22 is arbitrary in such disposition of the insulating portions 23a, 23b and the columnar parts 22.

For example, a distance d1 between the columnar parts 22c, 22d including the insulating portion 23a interposed is shorter than a distance d2 between columnar parts 22e, 22f including the insulating portion 23b and the portion (for example, connection portion 18) of the stacked body 15 interposed. The distance d1 corresponds to a distance between the center of the columnar part 22c and the center of the columnar part 22d. The distance d2 corresponds to a distance between the center of the columnar part 22e and the center of the columnar part 22f. The distance d2 is generally the same as a distance between the columnar parts 22a1, 22b1. The distance d2 is generally the same as a distance between the columnar parts 22a2, 22b2. The distance between the columnar parts 22 corresponds to a distance between the centers of the cylinder in the case of the shape of the columnar part 22 being cylindrical shape.

Hereinafter, an example of a method for manufacturing the semiconductor memory device according to the embodiment will be described.

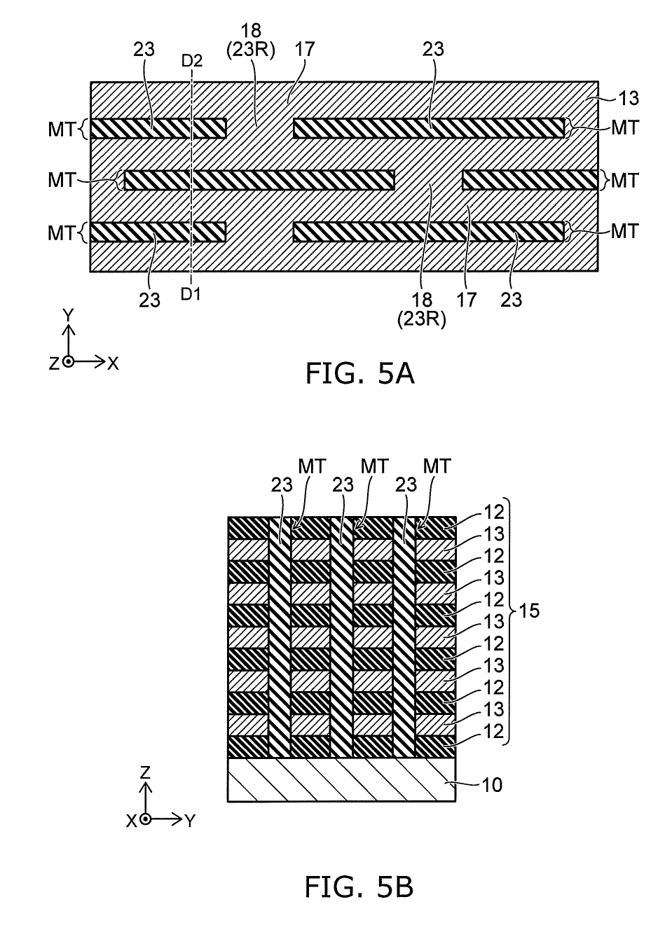

FIG. 5A and FIG. 5B to FIG. 9A and FIG. 9B are schematic views showing a method for manufacturing the semiconductor memory device according to the first embodiment.

FIG. 5A to FIG. 9A are plan views, and regions shown in FIG. 5A to FIG. 9A correspond to regions shown in FIG. 1. FIG. 5B to FIG. 9B are cross-sectional views of D1-D2 line of FIG. 5A to FIG. 9A.

Firstly, as shown in FIG. 5A and FIG. 5B, the insulating films 12 and the electrode films 13 are formed alternately on the substrate 10 by, for example, CVD (Chemical Vapor Deposition) method, and the stacked body 15 is formed. For example, the insulating films 12 are formed of a silicon oxide, and the electrode films 13 are formed of polysilicon.

Subsequently, the stacked body 15 is selectively removed by anisotropic etching such as, for example, a photolithography method and RIE (Reactive Ion Etching) or the like. Thereby, the multiple memory trenches MT are formed in the stacked body 15. The substrate 10 is exposed on a bottom surface of the memory trench MT.

When viewed from the Z-direction, the shape of the memory trench MT is rectangular, and a length in the X-direction is longer than a length in the Y-direction. The multiple memory trenches MT are formed along multiple columns extending in the X-direction. The electrode film 13 includes the interconnection portion 17 extending in the X-direction and the connection portion 18 disposed between the adjacent memory trenches MT in the X-direction and connecting the interconnection portions 17. The connection part 18 suppresses interconnection portion 17 from deforming or collapsing.

Subsequently, the insulating member 23 is formed in the memory trenches MT by, for example, CVD method. The insulating member 23 is formed of, for example, a silicon oxide. After that, the silicon oxide or the like on the stacked body 15 is removed by performing a flattening process such as CMP (Chemical Mechanical Polishing) or the like.

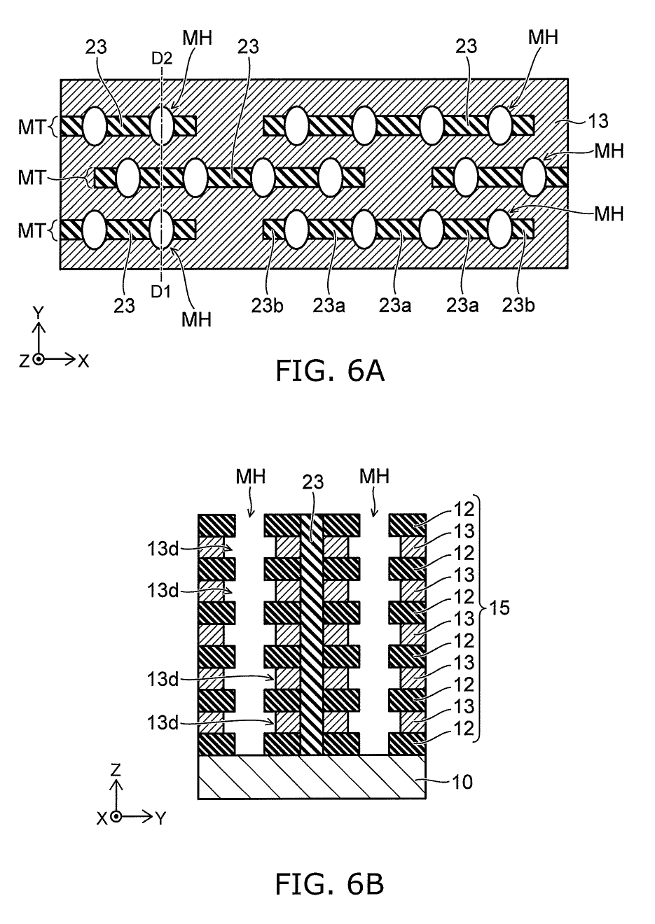

Next, as shown in FIG. 6A and FIG. 6B, the stacked body 15 is selectively removed by anisotropic etching such as a photolithography method and RIE or the like, for example.

Thereby, multiple memory holes MH are formed in the stacked body 15. The substrate 10 is exposed on a bottom surface of the memory hole MH. When viewed from the Z-direction, the shape of the memory holes MH is, for example, circle or oblong. The memory holes MH are formed in multiple columns extending in the X-direction, for example, in 3 columns.

The memory holes MH are formed to divide the insulating members 23. The multiple memory holes MH are disposed along the X-direction for each insulating member 23. Thereby, in each of the insulating members 23, 3 insulating portions 23a and 2 insulating portions 23b are formed. For example, the insulating portion 23a contacts the memory holes MH in the X-direction. For example, the insulating portion 23b contacts the memory hole MH at one end in the X-direction, and contacts a portion of the stacked body 15 at other end in the X-direction.

Subsequently, the electrode film 13 is etched via the memory hole MH. Thereby, an exposed surface of the electrode film 13 recedes in an inner wall surface of the memory hole MH, and a recess 13d is formed. The recess 13d is formed on both sides of the memory hole MH in the Y-direction and the shape of the recess 13d is semicircular.

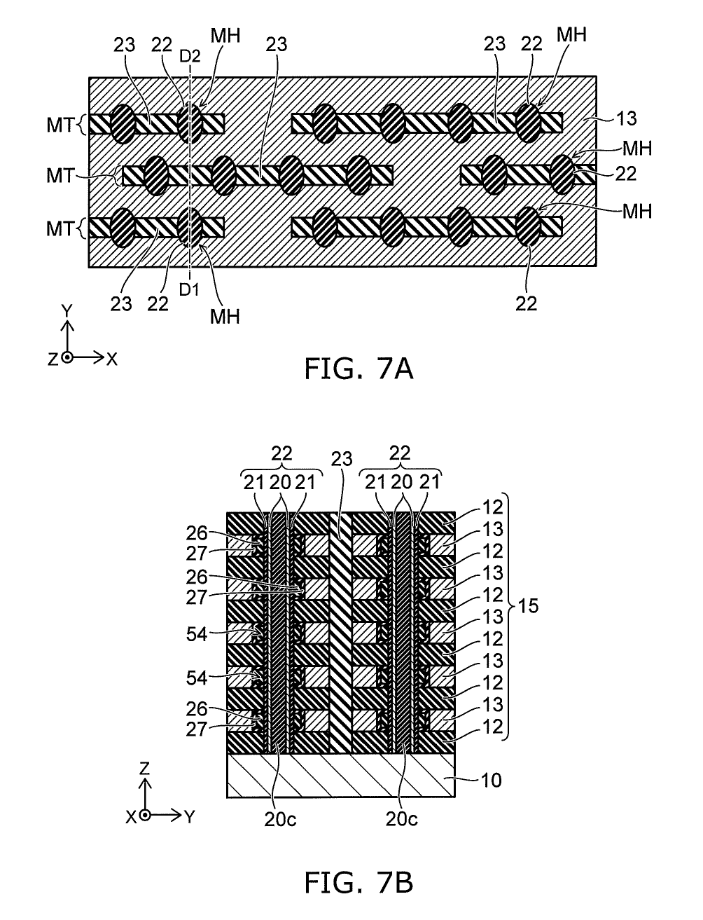

Next, as shown in FIG. 7A and FIG. 7B, after the insulating film 27 is formed on an inner surface of the recess 13d via the memory hole MH, the charge storage film 26 is formed on a surface of the insulating film 27. For example, the insulating film 27 is formed of a silicon oxide, and the charge storage film 26 is formed of a silicon nitride.

Subsequently, a portion formed outside the recess 13d in the charge storage film 26 and the insulating film 27 is removed via the memory hole MH by performing isotropic etching such as, for example, wet etching or CDE (Chemical Dry Etching) or the like. Thereby, the charge storage film 26 and the insulating film 27 are divided for each recess 13d.

Subsequently, the insulating film 21 is formed on the inner wall surface of the memory hole MH by the CVD method, for example. Next, the silicon pillar 20 (including a core part 20C) is formed by burying the memory hole MH with silicon and a silicon oxide. Thereby, the columnar part 22 including the silicon pillar 20 and the insulating film 21 is formed.

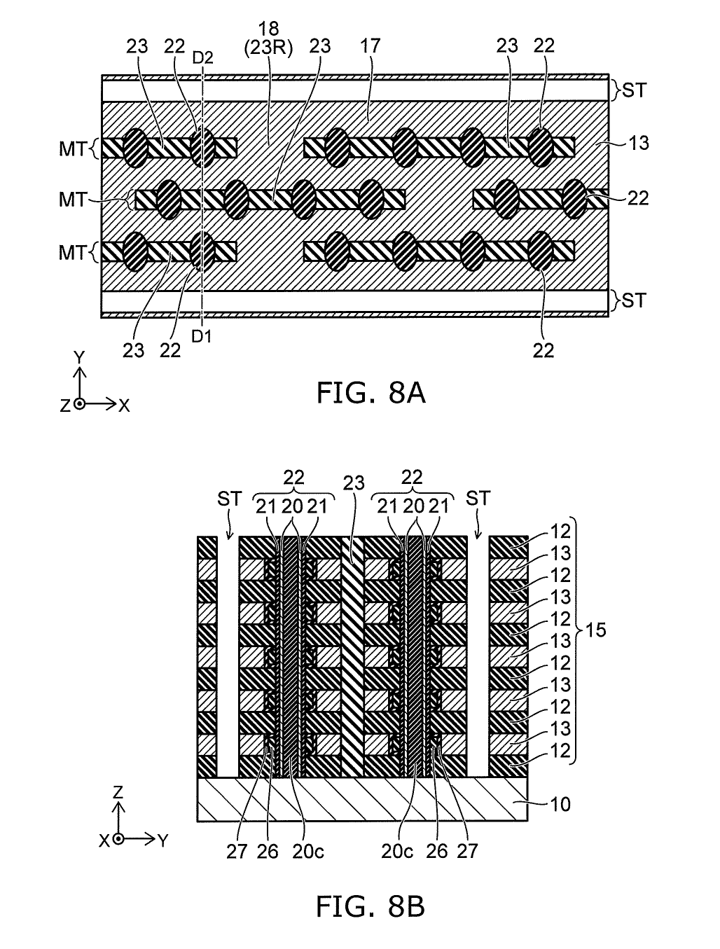

Next, as shown in FIG. 8A and FIG. 8B, the stacked body 15 is selectively removed by anisotropic etching such as a photolithography method and RIE or the like, for example. Thereby, the slit ST extending in the X-direction is formed in the stacked body 15. The slit ST is formed on both sides of the multiple columnar parts 22 in 3 columns in the Y-direction. The substrate 10 is exposed on a bottom surface of the slit ST.

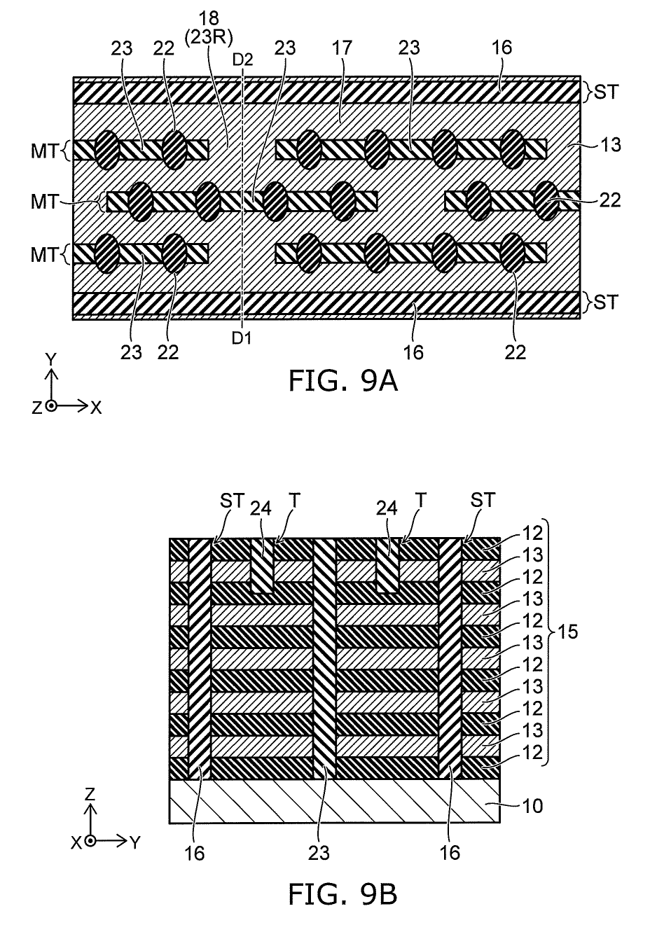

Next, as shown in FIG. 9A and FIG. 9B, the stacked body 15 is selectively removed by anisotropic etching such as a photolithography method and RIE or the like. Thereby, the groove T is formed in an upper portion of the stacked body 15. The groove T divides one from the top or multiple electrode films 13 (one in FIG. 9B), however does not divide the electrode films 13 below the one from the top.

Subsequently, the insulating member 16 is formed in the slit ST by the CVD method, for example, and the insulating member 24 is formed in the groove T. The insulating members 16, 24 are formed of, for example, a silicon oxide. After that, the silicon oxide or the like on the stacked body 15 is removed by performing the flattening process such as CMP or the like. FIG. 9A corresponds to a view of the electrode films 13 of the stacked body 15 (for example, source side selection gate SGS and word lines WL) viewed from above.

In this way, the semiconductor memory device 110 according to the embodiment is manufactured.

For example, in the 3-dimensional semiconductor memory device, a memory cell is formed for each cross portion of the electrode film and the channel (silicon pillar), and the memory hole is divided by multiple grooves (memory trenches) extending in the stacked body. For example, in the case where the multiple memory holes are disposed in a direction (for example, X-direction) in which the electrode films extend in the stacked body, the grooves are formed to extend in the X-direction and divide the memory holes. A structure body including such grooves and memory holes is multiply disposed in a direction (for example, Y-direction) crossing the direction in which the electrode films extend. A third direction is, for example, the Y-direction.

However, in the semiconductor memory device like this, the multiple grooves are disposed in the Y-direction so that each groove extends in the X-direction. Therefore, there is a fear that the stacked body is deformed or collapsed by the multiple grooves and the memory holes are hard to be formed. The memory holes are hard to be formed, and thus the silicon pillar and the charge storage film are hard to be formed in the memory hole.

In order to suppress the deformation and collapse of the stacked body, it is considered that a distance between the memory holes in the X-direction is elongated with a prescribed periodicity, and the adjacent grooves in the Y-direction are connected to divide the grooves extending in the X-direction. However, if the grooves and the memory holes are formed in this manner, interconnection capacity in the electrode film increases and interconnection delay (RC delay) occurs easily in the portion connecting the grooves in the Y-direction. Thereby, electric characteristics of the semiconductor memory device are degraded.

In the semiconductor memory device 110 according to the embodiment, the electrode films 13 (for example, word lines WL) includes the multiple interconnection portions 17 extending in the X-direction and the connection portion 18 positioned between the adjacent insulating members 23 in the X-direction and connecting the interconnection portions 17. The portion of the stacked body 15 including the connection portion 18 is positioned as a supporting body between the adjacent insulating members 23 in the X-direction.

Because the multiple insulating members 23 are disposed to be separated one another along the X-direction via the portion of the stacked body 15 including the connection portion 18 in the embodiment, the deformation and the collapse of the stacked body 15 are suppressed. For example, because, like processes of FIG. 5A and FIG. 5B, the portion of the stacked body 15 including the connection portion 18 functions as the supporting body when the memory trenches MT are formed, the deformation and the collapse of the stacked body 15 is suppressed.

In the embodiment, the multiple interconnection portions 17 of the electrode film 13 extend in the X-direction so that the adjacent insulating members 23 in the Y-direction are not connected. Thereby, the increase of the interconnection capacity in the electrode film 13 is suppressed and the interconnection delay is suppressed from occurring. Because the multiple interconnection portions 17 contribute to a current path in the electrode film 13, a current flows easily in the electrode film 13. Therefore, the electric characteristics of the semiconductor memory device are improved.

As described above, the semiconductor memory device 110 according to the embodiment includes the stacked body 15 (see FIG. 3), a first memory group MP1 (see FIG. 1), and a second memory group MP2 (see FIG. 1). The stacked body 15 includes the multiple electrode films 13. The multiple electrode films 13 are separated one another in the first direction (Z-direction). The first memory group MP1 and the second memory group MP2 are provided in the stacked body 15.

The first memory group MP1 includes multiple first columnar parts (columnar parts 22 including the columnar part 22c and the columnar part 22d). The multiple first columnar parts extend in the first direction (Z-direction). The multiple first columnar parts are arranged to be separated one another along the second direction. The second direction crosses the first direction. In the example of FIG. 1, the second direction is the X-direction. The insulating portion 23a is provided between the multiple first columnar parts. The insulating portion 23b is provided between one of the multiple first columnar parts and the stacked body 15 (multiple electrode films 13).

The second memory group MP2 includes multiple second columnar parts (columnar parts 22 including the columnar part 22f). The multiple second columnar parts extend in the first direction (Z-direction). The multiple second columnar parts are arranged to be separated one another along the second direction (X-direction). The insulating portion 23a is provided between the multiple second columnar parts. The insulating portion 23b is provided between one of the multiple second columnar parts and the stacked body 15 (multiple electrode films 13).

A portion 13p of the multiple electrode films 13 is provided between the first memory group MP1 and the second memory group MP2 (see FIG. 1). A direction from the first memory group MP1 toward the second memory group MP2 is aligned with the second direction (X-direction).

The multiple first columnar parts include a first proximal columnar part 22A closest to the second memory group MP2. The multiple second columnar parts include a second proximal columnar part 22B closest to the first memory group MP1. The center portion in the second direction (X-direction) of the first proximal columnar part 22A is taken as a first center portion cp1 (see FIG. 1). The center portion in the second direction of the second proximal columnar part 22B is taken as a second center portion cp2 (see FIG. 1).

A pitch (distance d1: see FIG. 1) of the multiple first columnar parts is shorter than a distance d2 (length along the X-direction, see FIG. 1) between the first center portion cp1 and the second center portion cp2.

The semiconductor memory device 110 according to the embodiment may further include a third memory group MP3 (see FIG. 1). The third memory group MP3 is provided in the stacked body 15. The third memory group MP3 includes multiple third columnar parts (columnar parts 22 including the columnar part 22b1: see FIG. 1). The multiple third columnar parts extend in the first direction (Z-direction). The multiple third columnar parts are arranged to be separated one another along the second direction (X-direction).

The third memory group MP3 overlaps a portion of the first memory group MP1 and a portion of the second memory group MP2 in the third direction. The third direction crosses a plane (Z-X plane) including the first direction (Z-direction) and the second direction (X-direction). The third direction is, for example, the Y-direction.

Another portion of the multiple electrode films 13 (portion 13q) is provided between the above portion of the first memory group MP1 and the third memory group MP3 and between the above portion of the second memory group MP2 and the third memory group MP3.

For example, a pitch of the multiple third columnar parts (columnar parts 22 including the columnar part 22b1: see FIG. 1) is the same as the distance d1. The pitch of the multiple third columnar parts is shorter than the above distance (distance d2) between the first center portion cp1 and the second center portion cp2.

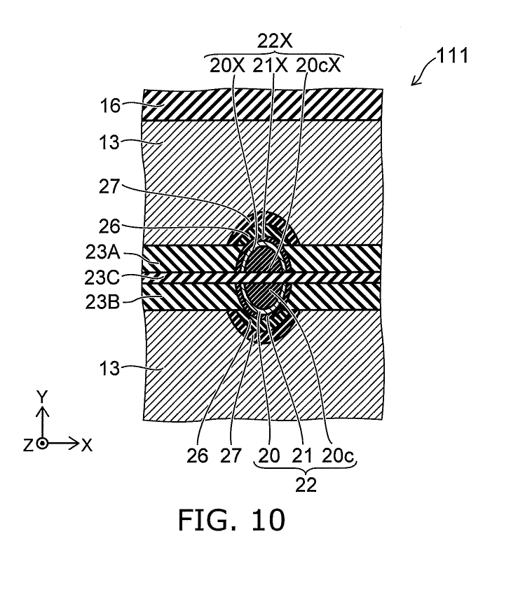

FIG. 10 is a schematic cross-sectional view showing an another semiconductor memory device according to the first embodiment.

As shown in FIG. 10, in a semiconductor memory device 111 according to the first embodiment, insulating regions 23A to 23C are provided as the insulating member 23 (see FIG. 2) in the semiconductor memory device 110. The insulating region 23A is provided in the Y-direction between the insulating region 23C and one region of the electrode films 13. The insulating region 23B is provided in the Y-direction between the insulating region 23C and another one region of the electrode film 13.

As shown in FIG. 10, one columnar part 22 (see FIG. 2) is divided into two columnar sub-parts (columnar parts 22 and 22X) by the insulating region 23C. The columnar part 22X includes a silicon pillar 20X (semiconductor part), an insulating film 21X and a core part 20c X.

The configuration of the semiconductor memory device 111 other than the above is similar to the semiconductor memory device 110. For example, the pitch (distance d1: see FIG. 1) of the multiple first columnar parts is shorter than the distance d2 between the first center portion cp1 and the second center portion cp2. Also in the semiconductor memory device 111, a semiconductor memory device capable of improving a memory density can be provided.

### Second Embodiment

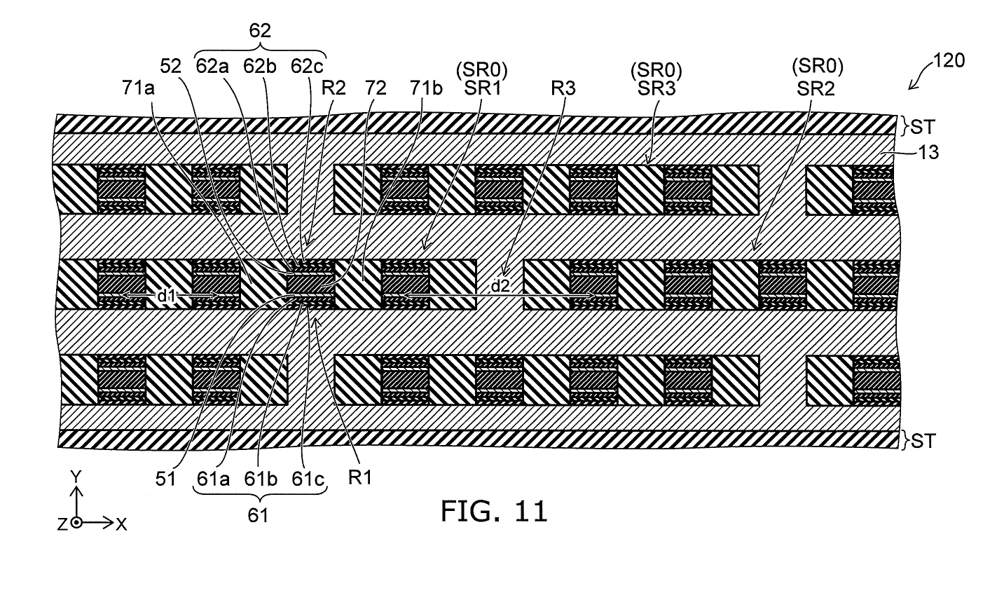

FIG. 11 is a schematic plan view illustrating a semiconductor memory device according to a second embodiment.

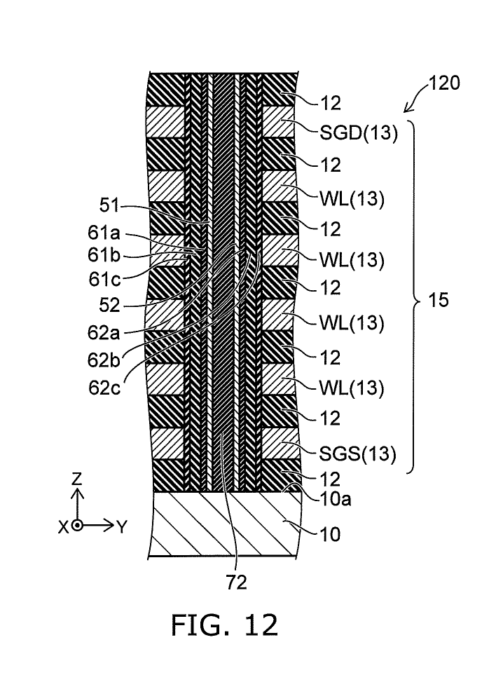

FIG. 12 is a schematic cross-sectional view illustrating the semiconductor memory device according to the second embodiment.

As shown in FIG. 11 and FIG. 12, a semiconductor memory device 120 according to the embodiment includes the stacked body 15, a first insulating region 71a, a second insulating region 71b, a first semiconductor member 51, a second semiconductor member 52, a first intermediate insulating region 72, a first memory part 61 and a second memory part 62.

The stacked body 15 includes the multiple electrode films (see FIG. 12). The multiple electrode films 13 are separated one another in the first direction.

The first direction is taken as the Z-direction. One direction perpendicular to the first direction is taken as the X-direction. A direction perpendicular to the Z-direction and the X-direction is taken as the Y-direction.

One of the multiple electrode films 13 includes a first partial region R1 and a second partial region R2. A direction from the first partial region R1 toward the second partial region R2 is aligned with the third direction (Y-direction), for example.

The first insulating region 71a is provided between the first partial region R1 and the second partial region R2.

The second insulating region 71b is provided between the first partial region R1 and the second partial region R2. A direction from the first insulating region 71a toward the second insulating region 71b is aligned with the second direction. The second direction crosses a plane (Y-Z plane) including the third direction (Y-direction) from the first partial region R1 toward the second partial region R2 and the first direction (Z-direction). The second direction is, for example, the X-direction.

As shown in FIG. 11, the first semiconductor member 51 passes through a region between the first partial region R1 and the second partial region R2 between the first insulating region 71a and the second insulating region 71b. As shown in FIG. 12, the first semiconductor member 51 extends in the first direction (Z-direction).

As shown in FIG. 11, the second semiconductor member 52 passes through a region between the first semiconductor member 51 and the second partial region R2 between the first insulating region 71a and the second insulating region 71b. As shown in FIG. 12, the second semiconductor member 52 extends in the first direction (Z-direction).

As shown in FIG. 11, the first intermediate insulating region 72 is provided between the first semiconductor member 51 and the second semiconductor member 52. The first intermediate insulating region 72 contacts the first insulating region 71a and the second insulating region 71b.

The first memory part 61 is provided between the first partial region R1 and the first semiconductor member 51. The second memory part 62 is provided between the second partial region R2 and the second semiconductor member 52.

The first memory part 61 includes, for example, a first inside insulating film 61a, a first charge storage film 61b and a first outside insulating film 61c. The first charge storage film 61b is provided between the first semiconductor member 51 and the first partial region R1. The first inside insulating film 61a is provided between the first semiconductor member 51 and the first charge storage film 61b. The first outside insulating film 61c is provided between the first partial region R1 and the first charge storage film 61b.

The second memory part 62 includes, for example, a second inside insulating film 62a, a second charge storage film 62b and a second outside insulating film 62c. The second charge storage film 62b is provided between the second semiconductor member 52 and the second partial region R2.

The second inside insulating film 62a is provided between the second semiconductor member 52 and the second charge storage film 62b. The second outside insulating film 62c is provided between the second partial region R2 and the second charge storage film 62b.

The first inside insulating film 61a and the second inside insulating film 62a function as, for example, a tunnel insulating film. The first outside insulating film 61c and the second outside insulating film 62c function as, for example, a block insulating film. These insulating films include, for example, silicon and oxygen.

The first charge storage film 61b and the second charge storage film 62b hold a charge, for example. The first charge storage film 61b and the second charge storage film 62b may be either insulative or conductive, for example. The first charge storage film 61b and the second charge storage film 62b may be a floating gate, a circumstance of the floating gate being surrounded by an insulator, for example. The first charge storage film 61b and the second charge storage film 62b include, for example, silicon and nitrogen. The first charge storage film 61b and the second charge storage film 62b may include, for example, silicon (for example, polysilicon).

As shown in FIG. 11, the first insulating region 71a, the second insulating region 71b, the first semiconductor member 51, the second semiconductor member 52, the first memory part 61 and the second memory part 62 are included in a structure body SR0. Multiple structure bodies SR0 (for example, first structure body SR1 and second structure body SR2 or the like) are provided.

A direction from the first structure body SR1 toward the second structure body SR2 is aligned with the second direction (X-direction).

The above one of the multiple electrode films 13 includes a third partial region R3. The third partial region R3 is provided between the first structure body SR1 and the second structure body SR2. The third partial region R3 is continuous to the first partial region R1 and the second partial region R2.

Also in the semiconductor memory device 120, a low resistance is obtained in the electrode film 13 by the third partial region R3. Also in the case of the memory density being increased, stable operation can be obtained. According to the embodiment, a semiconductor memory device capable of improving the memory density can be provided.

As shown in FIG. 11, the multiple structure bodies SR0 may further include a third structure body SR3. A direction from a portion of the first structure body SR1 toward a portion of the third structure body SR3 is aligned with the third direction (for example, Y-direction). A direction from the third partial region R3 toward another portion of the third structure body SR3 is aligned with the third direction (for example, Y-direction). A direction from a portion of the second structure body SR2 toward still another portion of the third structure body SR3 is aligned with the third direction (for example, Y-direction).

In this example, a direction from the third partial region R3 toward the first semiconductor member 51 included in the third structure body SR3 is aligned with the third direction (Y-direction).

As shown in FIG. 11, in the semiconductor memory device 120, the distance d1 is shorter than the distance d2. The distance d1 corresponds to, for example, a pitch of the multiple semiconductor members (multiple first semiconductor members 51) arranged along the second direction and included in the first structure body SR1. The multiple first semiconductor members 51 included in the first structure body SR1 include the first semiconductor member 51 closest to the second structure body SR2. The multiple first semiconductor members 51 included in the second structure body SR2 include the first semiconductor member 51 closest to the first structure body SR1. The distance d1 is shorter than the distance d2 (see FIG. 11) between the center portion in the second direction (X-direction) of the above first semiconductor member 51 closest to the second structure body SR2 and the center portion in the second direction (X-direction) of the above first semiconductor member 51 closest to the first structure body SR1.

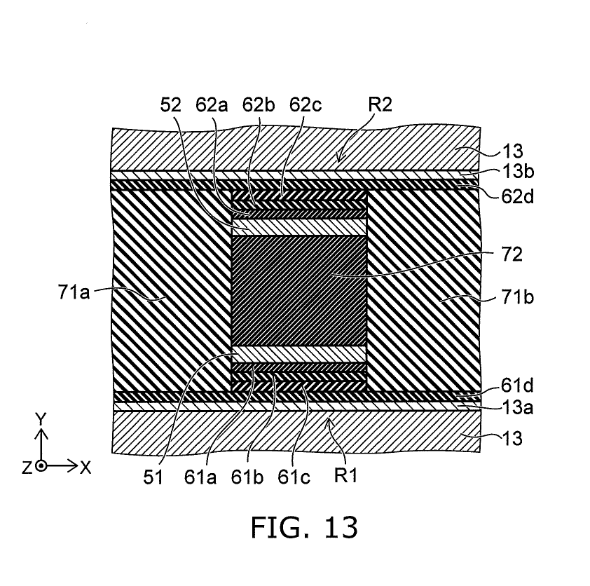

FIG. 13 is an another schematic cross-sectional view illustrating a portion of the semiconductor memory device according to the second embodiment. As shown in FIG. 13, in this example, an insulating film 61d is provided between the first semiconductor member 51 and the first partial region R1. A first intermediate film 13a is provided between the insulating film 61d and the first partial region R1. In this example, an insulating film 62d is provided between the second semiconductor member 52 and the second partial region R2. A second intermediate film 13b is provided between the insulating film 62d and the second partial region R2. The insulating film 61d and the insulating film 62d include, for example, an aluminum oxide. The first intermediate film 13a and the second intermediate film 13b include, for example, TiN.

The insulating film 61d may function as a portion of a block insulating film of the first memory part 61. The insulating film 62d may function as a portion of a block insulating film of the second memory part 62. The insulating film 61d, the insulating film 62d, the first intermediate film 13a, and the second intermediate film 13b are provided, for example, so as to surround an upper surface, a lower surface and a side surface of the electrode film 13 without extending through the stacked body 15 in the first direction (Z-direction).

Hereinafter, a method for manufacturing the semiconductor memory device 120 will be described.

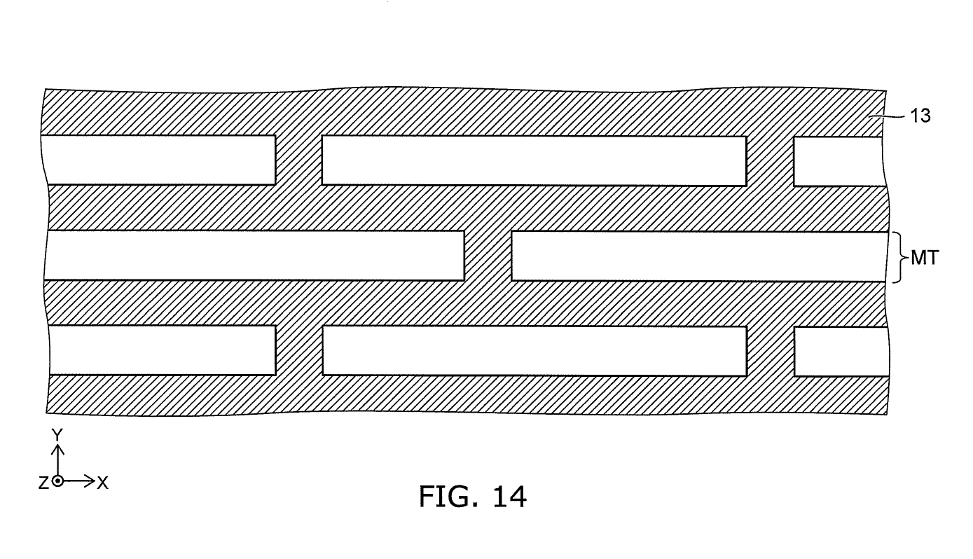

FIG. 14 to FIG. 17 are schematic plan views illustrating a method for manufacturing the semiconductor memory device according to the second embodiment.

As shown in FIG. 14, multiple memory trenches MT are formed in the electrode film 13 (stacked body 15).

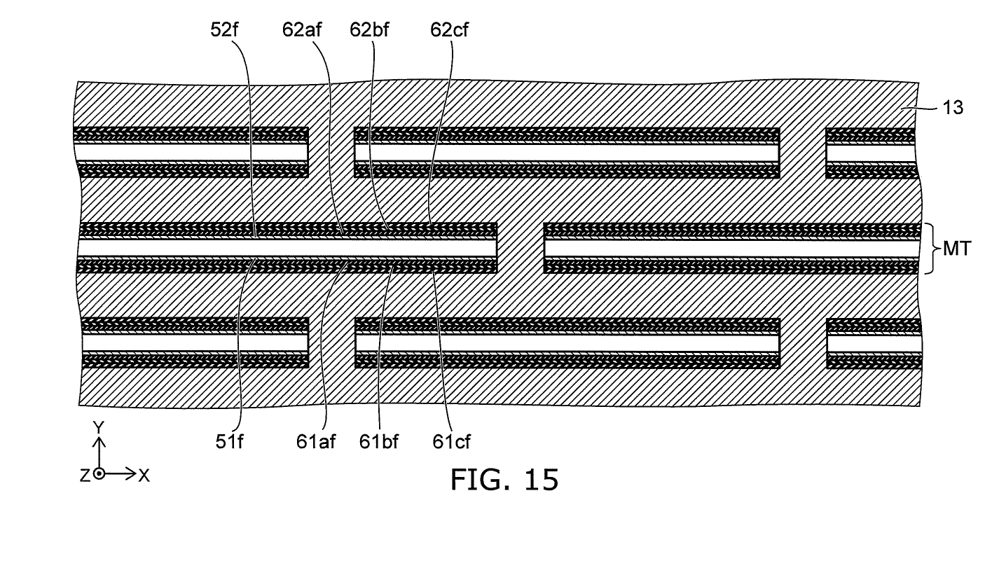

As shown in FIG. 15, a film 61af, a film 61bf, a film 61cf, a film 51f, a film 62af, a film 62bf, a film 62cf, a film 52f are formed in each of the multiple memory trenches MT. The film 61af serves as the first inside insulating film 61a. The film 61bf serves as the first charge storage film 61b. The film 61cf serves as the first outside insulating film 61c. The film 51f serves as the first semiconductor member 51. The film 62af serves as the second inside insulating film 62a. The film 62bf serves as the second charge storage film 62b. The film 62cf serves as the second outside insulating film 62c. The film 52f serves as the second semiconductor member 52.

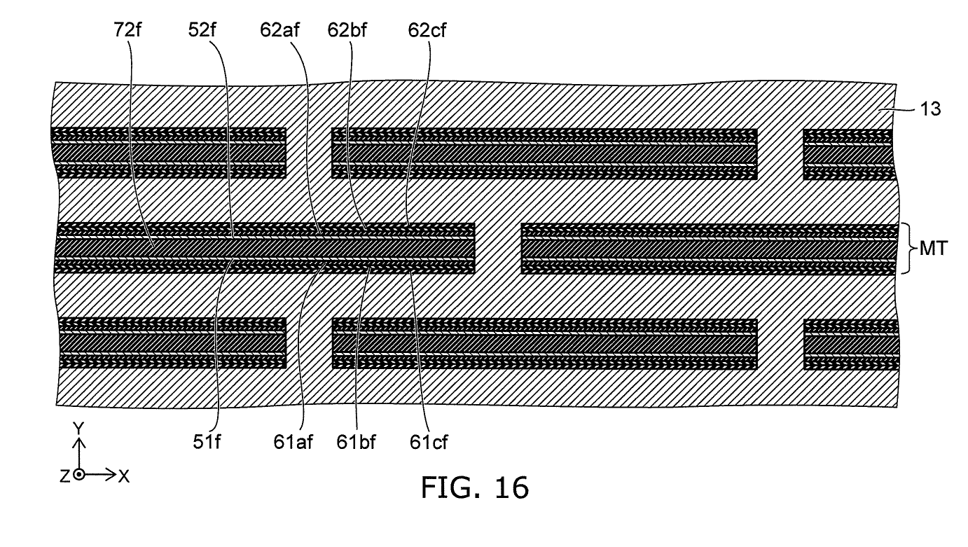

As shown in FIG. 16, a film 72f is formed in a residual space of each of the multiple memory trenches MT. The film 72f serves as the first intermediate insulating region 72.

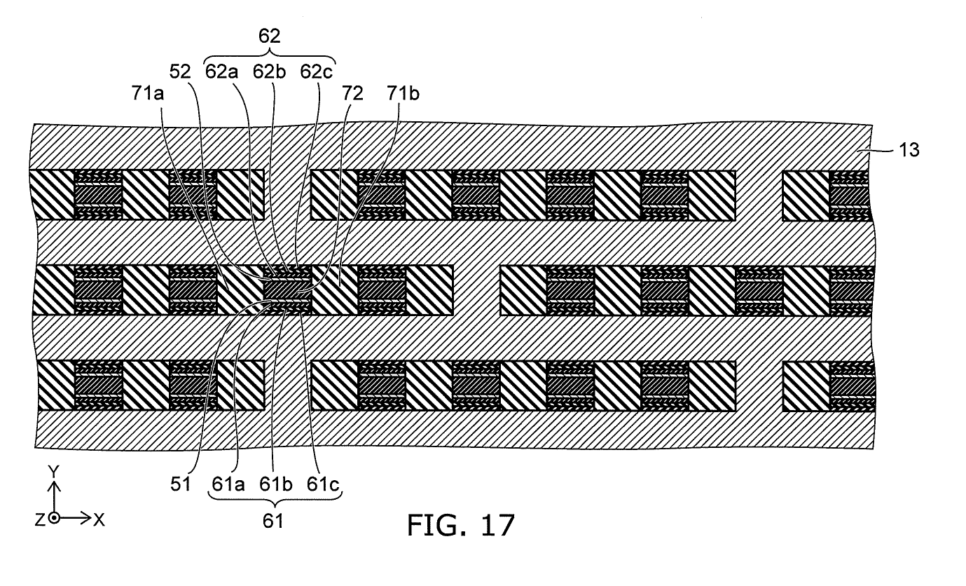

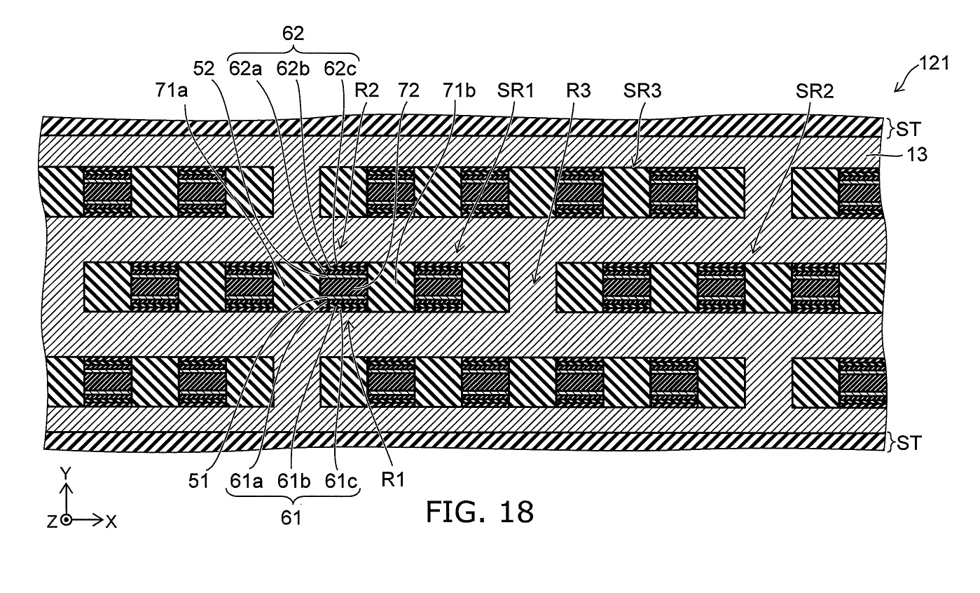

As shown in FIG. 17, in each of the multiple memory trenches MT, a portion of each of the film 61af, the film 61bf, the film 61cf, the film 51f, the film 62af, the film 62bf, the film 62cf, the film 52f, and the film 72f is removed. The space formed by removal is buried with an insulating material. Thereby, the multiple insulating regions (first insulating region 71a and second insulating region 71b or the like) are formed. The first semiconductor member 51, the second semiconductor member 52, the first memory part 61, the second memory part 62, and the first intermediate insulating region 72 are also formed.

After that, the insulating members are formed in the slit (not shown) extending through the stacked body 15 and in the groove (not shown) located at the upper portion of the stacked body 15. Thereby, the semiconductor memory device 120 is manufactured.

FIG. 18 is a schematic plan view illustrating a still another semiconductor memory device according to the second embodiment.

As shown in FIG. 18, a semiconductor memory device 121 according to the embodiment also includes the stacked body 15, the first insulating region 71a, the second insulating region 71b, the first semiconductor member 51, the second semiconductor member 52, the first intermediate insulating region 72, the first memory part 61 and the second memory part 62. Positions of the multiple semiconductor members in the semiconductor memory device 121 are different from positions of the multiple semiconductor members in the semiconductor memory device 120. The configuration of the semiconductor memory device 121 other than this is similar to the configuration of the semiconductor memory device 120.

In the semiconductor memory device 121, a direction from the third partial region R3 toward the first insulating region 71a included in the third structure body SR3 is aligned with the third direction (Y-direction). Also in the semiconductor memory device 121, a low resistance can be obtained in the electrode film 13 by the third partial region R3. Also in the case of the memory density being increased, stable operation can be obtained. According to the embodiment, a semiconductor memory device capable of improving the memory density can be provided.

According to the embodiments, a semiconductor memory device capable of improving the memory density is provided.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor memory device, comprising:
a substrate;
a stacked body provided above the substrate, the stacked body including a plurality of electrode films stacked to be separated one another in a first direction;
a plurality of columnar parts provided in the stacked body, each of the columnar parts including a semiconductor part extending in the first direction; and
a plurality of insulating members provided in the stacked body, each of the insulating members including a plurality of insulating portions disposed alternately with the columnar parts along a second direction crossing the first direction and parallel to an upper surface of the substrate,
the insulating members including a first insulating member, a second insulating member and a third insulating member, the first insulating member and the second insulating member being disposed to be separated each other along the second direction, the third insulating member being positioned to be separated from the first insulating member and the second insulating member along a third direction crossing the second direction and parallel to the upper surface of the substrate, each of the first insulating member and the second insulating member overlapping a respective portion of the third insulating member when viewed from the third direction,
the insulating portions including at least one first insulating portion and a plurality of second insulating portions, the first insulating portion being positioned between the second insulating portions,
the electrode films including a first portion and a second portion, the first portion being positioned in the second direction between the first insulating member and the second insulating member, the second portion being connected to the first portion and being positioned in the third direction between the first insulating member and the third insulating member and between the second insulating member and the third insulating member, the second portion extending in the second direction,
the columnar parts including a first columnar part, a second columnar part, a third columnar part and a fourth columnar part, the first columnar part being positioned between the first insulating portion of the first insulating member and the second insulating portion of the first insulating member, the second columnar part being positioned between the first insulating portion of the second insulating member and the second insulating portion of the second insulating member, the second insulating portion of the first insulating member and the second insulating portion of the second insulating member opposing via the first portion of the electrode films, the third columnar part and the fourth columnar part opposing via the first insulating portion of the third insulating member, and
a distance in the second direction of the third columnar part and the fourth columnar part being shorter than a distance in the second direction of the first columnar part and the second columnar part.

2. The device according to claim 1, wherein
the first columnar part and the second columnar part oppose in the second direction via the second insulating portion of the first insulating member, the second insulating portion of the second insulating member, and a portion of the stacked body.

3. The device according to claim 1, wherein
the insulating members further include a fourth insulating member separated from the third insulating member along the second direction, and
the second insulating member overlaps the third insulating member and the fourth insulating member when viewed from the third direction.

4. The device according to claim 3, wherein
the second portion of the electrode films is further positioned in the third direction between the second insulating member and the fourth insulating member, and
the electrode films further include a third portion connected to the second portion, the third portion being positioned in the second direction between the third insulating member and the fourth insulating member.

5. The device according to claim 1, wherein
the insulating members further include a fifth insulating member and a sixth insulating member, a first portion of the third insulating member being positioned in the third direction between the first insulating member and the fifth insulating member, the sixth insulating member being positioned to be separated from the fifth insulating member along the second direction, a second portion of the third insulating member being positioned in the third direction between the second insulating member and the sixth insulating member,
the columnar parts further include a fifth columnar part and a sixth columnar part, the fifth columnar part being positioned between the first insulating portion of the fifth insulating member and the second insulating portion of the fifth insulating member, the sixth columnar part being positioned between the first insulating portion of the sixth insulating member and the second insulating portion of the sixth insulating member, the second insulating portion of the fifth insulating member and the second insulating portion of the sixth insulating member opposing via a fourth portion of the electrode films, and
the third columnar part and the fourth columnar part are positioned in a region surrounded by the first columnar part, the second columnar part, the fifth columnar part and the sixth columnar part.

6. The device according to claim 5, wherein
the columnar parts are arranged in a staggered arrangement when viewed from the first direction.

7. The device according to claim 1, further comprising:
a plurality of charge storage films provided in the stacked body and positioned on both sides in the third direction of the columnar parts.

8. The device according to claim 1, wherein
the electrode films include silicon.

9. The device according to claim 1, wherein
the columnar parts are divided into two sub-parts in the third direction by an insulator.

10. The device according to claim 1, wherein
a plurality of the first insulating portions are disposed between the second insulating portions in the second direction, and
the third columnar part and the fourth columnar part are positioned between the first insulating portions of the third insulating member.

11. A semiconductor memory device, comprising:
a stacked body including a plurality of electrode films, the electrode films being separated one another in a first direction; and
a first memory group provided in the stacked body and a second memory group provided in the stacked body,
the first memory group including a plurality of first columnar parts, the first columnar parts extending in the first direction, and being arranged to be separated one another along a second direction crossing the first direction,
the second memory group including a plurality of second columnar parts, the second columnar parts extending in the first direction, and being arranged to be separated one another along the second direction,
a first portion of the electrode films being provided between the first memory group and the second memory group,
a direction from the first memory group toward the second memory group being aligned with the second direction,
the first columnar parts including a first proximal columnar part closest to the second memory group,
the second columnar parts including a second proximal columnar part closest to the first memory group, and
a pitch of the first columnar parts being shorter than a distance between a first center portion in the second direction of the first proximal columnar part and a second center portion in the second direction of the second proximal columnar part.

12. The device according to claim 11, further comprising:
a third memory group provided in the stacked body,
the third memory group including a plurality of third columnar parts, the third columnar parts extending in the first direction, and being arranged to be separated one another along the second direction,
the third memory group overlapping a portion of the first memory group and a portion of the second memory group in a third direction crossing a plane including the first direction and the second direction, and
a second portion of the electrode films being provided between the third memory group and the portion of the first memory group and between the third memory group and the portion of the second memory group.

13. The device according to claim 11, further comprising:
a plurality of charge storage films provided in the stacked body and positioned on both sides in the third direction of the first columnar parts and the second columnar parts.

14. The device according to claim 11, wherein
a pitch of the second columnar parts is same as the pitch of the first columnar parts.

15. The device according to claim 11, wherein
each of the first columnar parts and the second columnar parts includes a semiconductor part extending in the first direction.

16. A semiconductor memory device, comprising:
a stacked body including a plurality of electrode films separated one another in a first direction, one of the electrode films including a first partial region and a second partial region;
a first insulating region provided between the first partial region and the second partial region;
a second insulating region provided between the first partial region and the second partial region, a second direction crossing a plane including a third direction and the first direction, the second direction being from the first insulating region toward the second insulating region, the third direction being from the first partial region toward the second partial region;
a first semiconductor member passing through a region between the first partial region and the second partial region between the first insulating region and the second insulating region, the first semiconductor member extending in the first direction;
a second semiconductor member passing through a region between the first semiconductor member and the second partial region between the first insulating region and the second insulating region, the second semiconductor member extending in the first direction;
a first intermediate insulating region provided between the first semiconductor member and the second semiconductor member, and contacting the first insulating region and the second insulating region;
a first memory part provided between the first partial region and the first semiconductor member; and
a second memory part provided between the second partial region and the second semiconductor member,
a first structure body and a second structure body being provided so as to be aligned with the second direction, each of the first structure body and the second structure body including the first insulating region, the second insulating region, the first semiconductor member, the second semiconductor member, the first memory part and the second memory part,
the one of the electrode films including a third partial region between the first structure body and the second structure body, the third partial region being continuous to the first partial region and the second partial region.

17. The device according to claim 16, wherein
a third structure body including the first insulating region, the second insulating region, the first semiconductor member, the second semiconductor member, the first memory part and the second memory part is further provided,
a direction from a portion of the first structure body toward a first portion of the third structure body is aligned with the third direction, and
a direction from the third partial region toward a second portion of the third structure body is aligned with the third direction.

18. The device according to claim 17, wherein
a direction from a portion of the second structure body toward a third portion of the third structure body is aligned with the third direction.

19. The device according to claim 17, wherein
a direction from the third partial region toward the first semiconductor member included in the third structure body is aligned with the third direction.

20. The device according to claim 17, wherein
a direction from the third partial region toward the first insulating region included in the third structure body is aligned with the third direction.
